(19) United States
(12) Patent Application Publication
(10) Pub. No.: US 2025/0105768 A1
(43) Pub. Date: Mar. 27, 2025

(54) MOTOR CONTROL DEVICE AND METHOD FOR ESTIMATING POSITION OF ROTOR THEREOF

(71) Applicants: HYUNDAI MOTOR COMPANY, Seoul (KR); Kia Corporation, Seoul (KR)

(72) Inventors: Chang Seok YOU, Hwaseong-si (KR); Sang Hak LIM, Suwon-si (KR); Min Su KANG, Paju-si (KR); Jae Hyung LEE, Yongin-si (KR)

(21) Appl. No.: 18/733,599

(22) Filed: Jun. 4, 2024

(30) Foreign Application Priority Data
Sep. 27, 2023 (KR) 10-2023-0131147

(51) Int. Cl. H02P 21/18; H02P 21/22; H02P 21/32; H02P 27/14

(52) U.S. Cl. CPC H02P 21/18; H02P 21/22; H02P 21/32; H02P 27/14

(57) ABSTRACT

A motor control device for estimating a position of a rotor in a state in which a motor is stopped and a method for estimating a position of a rotor thereof are provided. The motor control device includes a power supply, a current sensor, and a processor. The processor determines whether a rotor position estimation execution condition is established, applies a phase voltage to a stator of the motor, if it is determined that the rotor position estimation execution condition is established, measures the current flowing in the stator, estimates a position of a rotor of the motor based on a first maximum current value among the measured current values, and determines whether to reattempt to estimate a position of the rotor based on a difference between the first maximum current value and a second maximum current value among the measured current values.

### CROSS-REFERENCE TO RELATED APPLICATION

This application claims the benefit of priority to Korean Patent Application No. 10-2023-0131147, filed in the Korean Intellectual Property Office, on Sep. 27, 2023, the entire contents of which are incorporated herein by reference.

### TECHNICAL FIELD

The present disclosure relates to a motor control device for estimating a position of a rotor in a state in which a motor is stopped and a method for estimating a position of a rotor thereof.

### BACKGROUND

As a motor and an inverter are integrally developed in an air compressor applied to a third generation fuel cell, in some cases, it may be difficult to apply a rotor position sensor to the motor due to a package problem. In some cases, a rotor position sensorless (or position sensorless) technology is applied to execute motor control.

The position sensorless technology may estimate a speed and a position, when an expansion back electromotive force of the motor is formed. Because the back electromotive force is 0 V when the motor is in the stopped state, it is impossible to estimate a speed and a position depending on the estimation of the expansion back electromotive force. Thus, because the motor starts to drive in a state in which the position of a rotor is not known when it is driven in the stopped state, there is a possibility that the motor may be driven from an incorrect position upon initial driving.

When the motor is driven from the incorrect position, sensorless driving fails due to divergence of a sensorless speed and position estimation feedback controller or a responsiveness delay phenomenon due to motor driving instability may occur upon initial driving. Thus, in some cases, a separate position estimation technology may be applied in the stopped state of the motor, or the rotor may be aligned at a specific position to be driven in a specific state.

### SUMMARY

The present disclosure describes a motor control device for applying a pulse voltage application scheme to improve the accuracy of the estimation of an initial position of a rotor even in a state in which a motor is stopped and a method for estimating a position of a rotor thereof.

According to an aspect of the present disclosure, a motor control device may include a power supply that supplies a phase voltage to a stator of a motor, a current sensor that measures current flowing in the stator, a processor connected with the power supply and the current sensor. The processor may determine whether a rotor position estimation execution condition is established, may apply the phase voltage to the stator of the motor, if it is determined that the rotor position estimation execution condition is established, may measure the current flowing in the stator, may estimate a position of a rotor of the motor based on a first maximum current value among the measured current values, and may determine whether to reattempt to estimate a position of the rotor based on a difference between the first maximum current value and a second maximum current value among the measured current values.

The processor may determine whether the difference between the first maximum current value and the second maximum current value is less than a predetermined reference value and may determine to reattempt to estimate the position of the rotor, if it is determined that the difference between the first maximum current value and the second maximum current value is less than the predetermined reference value.

The processor may change the position of the rotor, if it is determined to reattempt to estimate the position of the rotor, and may re-estimate the position of the rotor by reapplying the phase voltage to the stator, after changing the position of the rotor.

The processor may finally determine the estimated position of the rotor as an initial position of the rotor, if it is determined not to reattempt to estimate the position of the rotor.

The processor may determine that the rotor position estimation execution condition is established, if a stop command is transmitted to the motor and the motor switches from a rotational state to a stopped state.

The processor may wait during a predetermined time, until the rotor of the motor stops and may initiate to apply the phase voltage to the stator, if the predetermined time elapses.

The processor may apply and stop the phase voltage depending on a predetermined pulse duty cycle, and may wait until the current flowing in the stator is blocked and may apply a next phase voltage, if the current flowing in the stator is blocked.

The phase voltage may be a 3-phase voltage in the form of a pulse.

The processor may sense a current value in a first period of pulse width modulation (PWM), may sense a current value in a last period of the PWM, may calculate a difference between the current value in the first period and the current value in the last period, and may set the calculated current value difference to a phase voltage vector current.

The processor may identify a position at which the first maximum current value is stored in a phase voltage vector current array and may determine an angle in a phase voltage vector angle array mapped to the identified position as the position of the rotor.

According to another aspect of the present disclosure, a method for estimating a position of a rotor of a motor control device may include determining whether a rotor position estimation execution condition is established, applying a phase voltage to a stator of a motor, if it is determined that the rotor position estimation execution condition is established, measuring current flowing in the stator, estimating the position of the rotor of the motor based on a first maximum current value among the measured current values, and determining whether to reattempt to estimate the position of the rotor based on a difference between the first maximum current value and a second maximum current value among the measured current values.

The determining of whether to reattempt to estimate the position of the rotor may include determining whether the difference between the first maximum current value and the second maximum current value is less than a predetermined reference value and determining to reattempt to estimate the position of the rotor, if it is determined that the difference between the first maximum current value and the second maximum current value is less than the predetermined reference value.

The method may further include changing the position of the rotor, if it is determined to reattempt to estimate the position of the rotor, and re-estimating the position of the rotor by reapplying the phase voltage to the stator, after changing the position of the rotor.

The method may further include finally determining the estimated position of the rotor as an initial position of the rotor, if it is determined not to reattempt to estimate the position of the rotor.

The determining of whether the rotor position estimation execution condition is established may include determining that the rotor position estimation execution condition is established, if a stop command is transmitted to the motor and the motor switches from a rotational state to a stopped state.

The applying of the phase voltage to the stator of the motor may include waiting during a predetermined time, until the rotor of the motor stops, and initiating to apply the phase voltage to the stator, if the predetermined time elapses.

The applying of the phase voltage to the stator of the motor may include applying and stopping the phase voltage depending on a predetermined pulse duty cycle, and waiting until the current flowing in the stator is blocked and applying a next phase voltage, if the current flowing in the stator is blocked.

The measuring of the current may include sensing a current value in a first period of pulse width modulation (PWM), sensing a current value in a last period of the PWM, calculating a difference between the current value in the first period and the current value in the last period, and setting the calculated current value difference to a phase voltage vector current.

The estimating of the position of the rotor may include identifying a position at which the first maximum current value is stored in a phase voltage vector current array and determining an angle in a phase voltage vector angle array mapped to the identified position as the position of the rotor.

### BRIEF DESCRIPTION OF THE DRAWINGS

The above and other objects, features and advantages of the present disclosure will be more apparent from the following detailed description taken in conjunction with the accompanying drawings.

FIG. 1 is a graph illustrating an example of a change in speed of an air compressor when a fuel cell vehicle associated with the present disclosure travels.

FIG. 2 is a graph illustrating an example of a motor driving speed upon open loop control of a position sensorless motor associated with the present disclosure.

FIG. 3 is a drawing schematically illustrating an example of a motor for an air compressor associated with the present disclosure.

FIG. 4 is a block diagram illustrating an example of a configuration of a motor control device.

FIGS. 5A and 5B are graphs illustrating an example of driving a motor according to whether there is an error in an initial position of a rotor when deleting an open loop control interval associated with the present disclosure.

FIG. 6 is a drawing for describing an example of determining a time point when rotor position estimation associated with the present disclosure is performed.

FIGS. 7A and 7B are drawings for describing an example of a rotor initial position estimation scheme associated with the present disclosure.

FIG. 8 is a drawing for describing an example of rotor initial position estimation when stopping a motor associated with the present disclosure.

FIG. 9 is a drawing illustrating an example result of testing rotor initial position estimation associated with the present disclosure.

FIG. 10 is a drawing for describing an example of a phase voltage application scheme.

FIG. 11 is a drawing for describing an example of a current measurement scheme.

FIG. 12 is a drawing for describing an example of a rotor position derivation scheme.

FIG. 13 is a drawing for describing an example of a rotor position estimation reattempt scheme.

FIG. 14A is a drawing for describing an example of normal rotor position estimation.

FIG. 14B is a drawing for describing an example of rotor position re-estimation.

FIGS. 15A, 15B, and 15C are flowcharts illustrating an example of a method for estimating a position of a rotor of a motor.

### DETAILED DESCRIPTION

Hereinafter, one or more implementations of the present disclosure will be described in detail with reference to the exemplary drawings. In the drawings, the same reference numerals will be used throughout to designate the same or equivalent components.

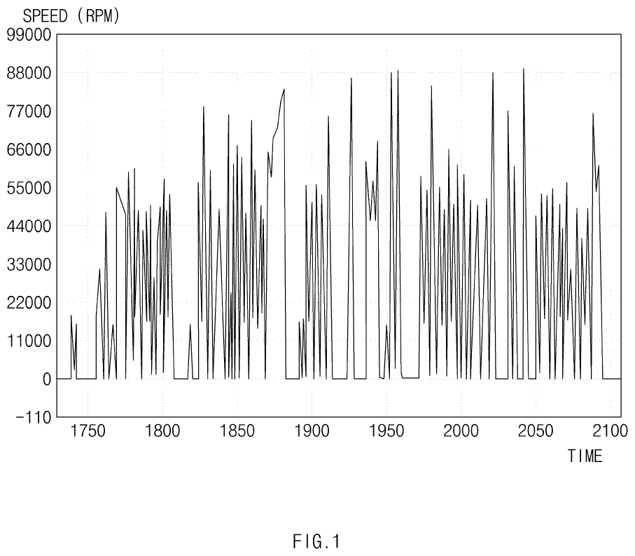

FIG. 1 is a graph illustrating an example of a change in speed of an air compressor when a fuel cell vehicle associated with the present disclosure travels.

In some implementations, referring to FIG. 1, because the air should be supercharged when a driver presses the accelerator pedal, a fuel cell vehicle may instantaneously increase a motor rotation speed of an air compressor (or an air compressor speed). In other words, the fuel cell vehicle may increase the motor rotation speed of the air compressor to supply a lot of air to its fuel cell stack, thus increasing the power of the vehicle to accelerate the vehicle. Furthermore, the fuel cell vehicle may stop its fuel cell when stopped and may allow the air compressor to be in a stopped state. Thereafter, when the vehicle restarts by its driver, the fuel cell vehicle may restart the air compressor which is in the stopped state. As such, the air compressor may frequently and repeatedly perform standstill and driving during one driving cycle.

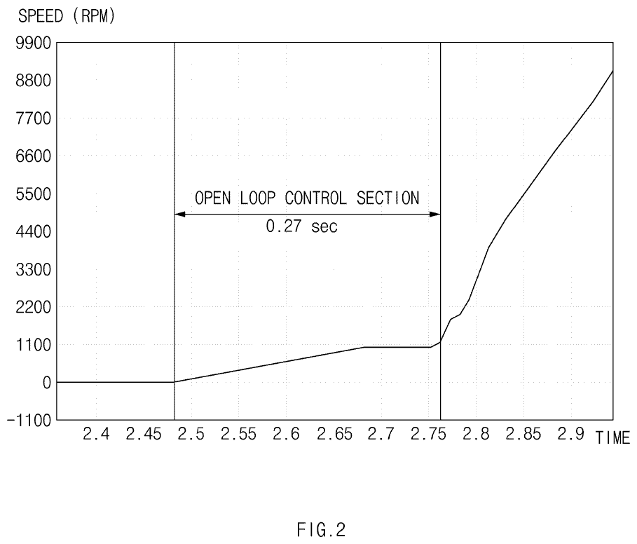

FIG. 2 is a graph illustrating a motor driving speed upon open loop control of a position sensorless motor associated with the present disclosure.

In some examples, when a motor to which a position sensor is not applied (or a position sensorless motor) starts initial driving from a stopped state without knowing an initial position of the rotor, a magnetic field may be formed on a stator from a time point when the rotor of the motor reaches a specific position and the rotor may rotate along the magnetic field of the stator by linearly increasing a rotation speed of the magnetic field. In this case, because the magnetic field of the stator should be formed and rotated slowly, the magnetic field is unable to be rotated at an extremely high speed. There is a need for an open loop control interval for rotating a magnetic field during a certain time to synchronize a driving speed (or a rotation speed) of the rotor with a rotation speed of the magnetic field. As shown in FIG. 2, when the position sensorless motor is initially driven without knowing the position of the rotor, an initial driving delay of about 0.27 seconds may occur. Such an initial driving delay of the motor may cause an air supply delay of the air compressor to degrade vehicle launch responsiveness.

The present disclosure describes a technology for deleting the open loop control interval to prevent the air supply delay due to the initial driving delay of the motor and estimating an initial position of the rotor when the rotor stops.

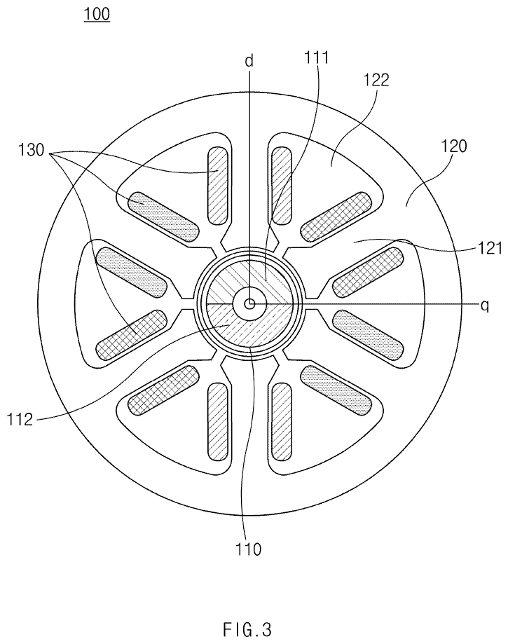

FIG. 3 is a drawing schematically illustrating a motor for an air compressor associated with the present disclosure.

In some implementations, referring to FIG. 3, a motor 100 may include a rotor 110 and a stator 120. The motor 100 may be a motor with saliency, a surface mounted permanent magnet synchronous motor (SPMSM) with no saliency, or the like.

The rotor 110 may include an N-pole permanent magnet 111 and an S-pole permanent magnet 112, which are attached to the surface. The rotor 110 may be rotatably disposed at a predetermined interval, that is, an air gap with the stator 120. The rotor 110 may rotate through an interaction with the stator 120.

The stator 120 may be disposed at an outer side of the rotor 110 and may be disposed to be fixed at an inner side of a motor housing. The stator 120 may include a plurality of teeth 121 formed to protrude in a radius direction at a predetermined interval in a circumferential direction of a body. Slots 122 may be formed between the teeth 121. The slot 122 may be defined as a space where a coil 130 wound on the teeth 121 is located.

When current is input from an inverter, the coil 130 wound on the teeth 121 may generate a first magnetic flux for driving the motor 100. As the first magnetic flux generated by the stator 120 and magnetic forces of the permanent magnets 111 and 112 interact with each other, the rotor 110 rotates.

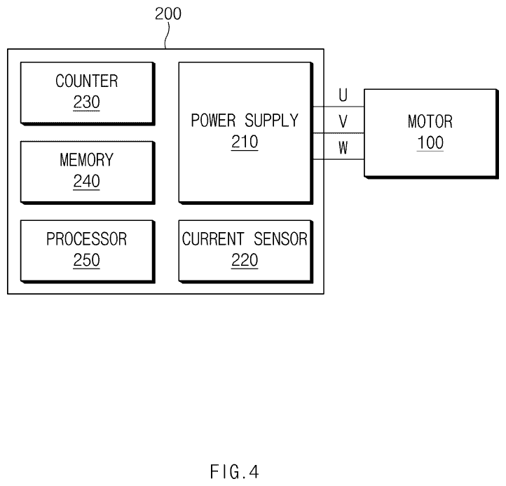

FIG. 4 is a block diagram illustrating a configuration of a motor control device.

Referring to FIG. 4, a motor control device 200 may control an operation of a motor 100, which may include a power supply 210, a current sensor 220, a counter 230, a memory 240, and a processor 250.

The power supply 210 may apply (or supply) a testing voltage to a coil 130 wound on a stator 120 depending on a control signal of the processor 250. A phase voltage (e.g., a 3-phase voltage) in the form of a pulse may be used as the testing voltage.

The current sensor 220 may measure current flowing in the coil 130 of the stator 120. The current sensor 220 may transmit the measured current value to the processor 250. The current sensor 220 may store the measured current value in the memory 240 depending on an instruction of the processor 250.

The counter 230 may count the number of specific signals. The counter 230 may transmit the counted number to the processor 250. Furthermore, the counter 230 may store the counted value (or a count value) in the memory 240 depending on an instruction of the processor 250. It is shown in the drawing that the motor control device 200 includes the one counter 230, but not limited thereto. The motor control device 200 may include two or more counters.

The memory 240 may store the current value measured by the current sensor 220. The memory 240 may store pieces of predetermined setting information (e.g., a reference value or the like). The memory 240 may store a position estimation algorithm or the like.

The memory 240 may be a non-transitory storage medium which stores instructions executed by the processor 250. The memory 240 may be implemented as a flash memory, a hard disk, a solid state disk (SSD), a random access memory (RAM), a static RAM (SRAM), a read only memory (ROM), a programmable ROM (PROM), an electrically erasable and programmable ROM (EEPROM), an erasable and programmable ROM (EPROM), and/or the like.

The processor 250 may be electrically connected with the power supply 210, the current sensor 220, the counter 230, and the memory 240 and may control the overall operation of the motor control device 200. The processor 250 may be implemented as an application specific integrated circuit (ASIC), a digital signal processor (DSP), a programmable logic device (PLD), a field programmable gate array (FPGA), a central processing unit (CPU), a microcontroller, a microprocessor, and/or the like.

The processor 250 may estimate a position of the rotor 110 using the position estimation algorithm in a state in which the motor 100 is stopped. The processor 250 may estimate a rotor position of the motor 100 every pulse width modulation (PWM) period.

The processor 250 may determine whether a rotor position estimation execution condition is established. The processor 250 may determine whether the rotor position estimation execution condition is established based on a speed command, an estimated speed in an immediately previous period, an estimated speed in a current period, and/or the like. As an example, when the speed command transmitted to the motor 100 is 0 rpm and when the speed (or the motor speed) estimated in the immediately previous period is not 0 rpm and the speed estimated in the current period is 0 rpm, the processor 250 may determine that the rotor position estimation execution condition is established. In other words, when the stop command is transmitted to the motor 100 and when the motor 100 switches from a rotational state to a stopped state, the processor 250 may determine whether the rotor estimation execution condition is met (or satisfied).

When it is determined that the rotor position estimation execution condition is established, the processor 250 may wait during a predetermined time (or a waiting time) until the rotor 110 completely stops. At this time, the processor 250 may count the waiting time using the counter 230.

When the predetermined waiting time elapses, the processor 250 may control the power supply 210 to supply a phase voltage to the coil 130 of the stator 120. The power supply 210 may apply a phase voltage (e.g., a 3-phase voltage) in the form of a pulse to the stator 120 of the motor 100 depending on a command of the processor 250.

The processor 250 may supply the phase voltage to the stator 120 and may measure current flowing in the stator 120 using the current sensor 220. The processor 250 may estimate (or determine) a position of the rotor 110 based on the measured current value. The processor 250 may determine a position where a maximum current value among the measured current values is measured (or a phase voltage vector or a space voltage vector) as the position of the rotor 110.

The processor 250 may calculate a difference between a first maximum current value and a second maximum current value among the measured current values. The processor 250 may identify whether the calculated difference is less than a predetermined reference value. When the calculated difference is less than the predetermined reference value, the processor 250 may determine to reattempt to estimate a position of the rotor 110. In some examples, when the calculated difference is greater than or equal to the predetermined reference value, the processor 250 may determine not to reattempt to estimate the position of the rotor 110.

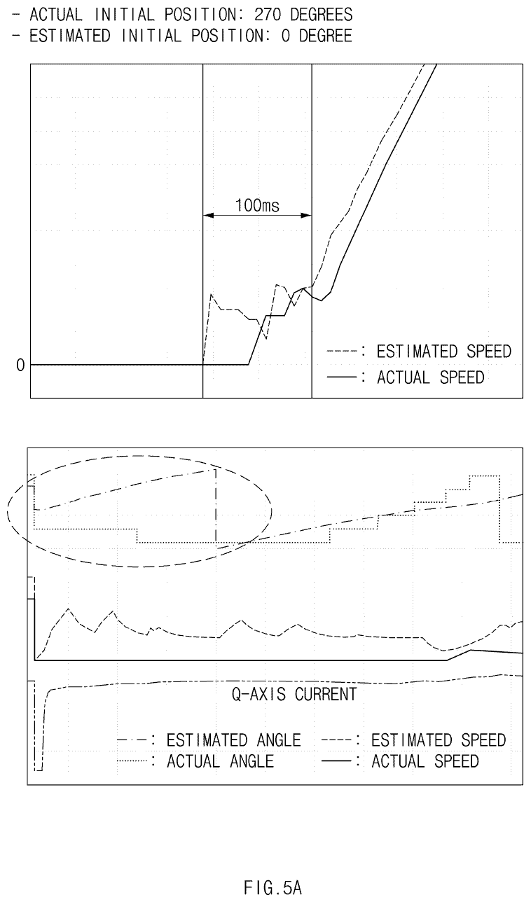

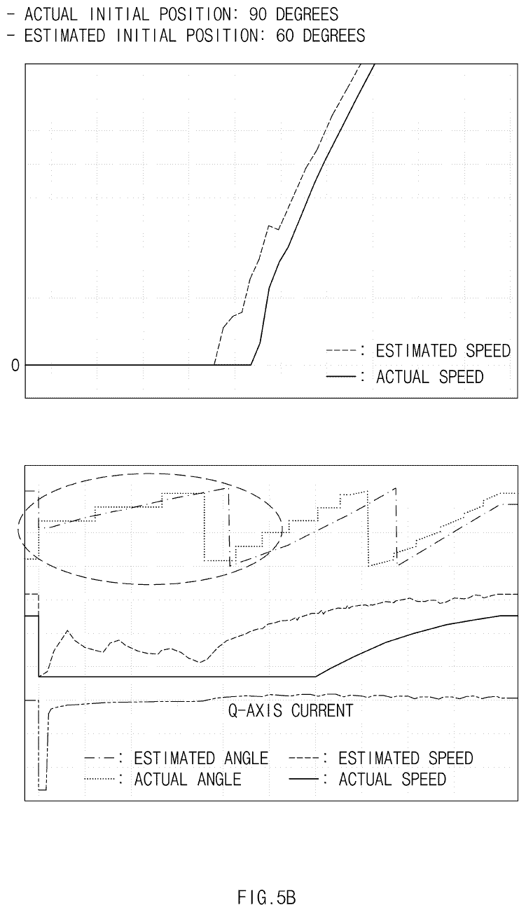

FIGS. 5A and 5B are graphs illustrating an example of driving a motor according to whether there is an error in an initial position of a rotor when deleting an open loop control interval associated with the present disclosure.

When incorrectly recognizing an initial position of a rotor 110 after deleting the open loop control interval, a motor control device 200 may execute motor control from the incorrect initial position of the rotor 110. Referring to FIG. 5A, when an initial position is incorrectly recognized, as driving synchronization fails at the beginning of driving, a driving delay of 0.1 second may occur.

Referring to FIG. 5B, when an initial position of the rotor 110 is accurately recognized after the open loop control interval is deleted, as driving synchronization is successful as soon as initial driving starts at the recognized initial position, motor driving may be performed without an initial delay.

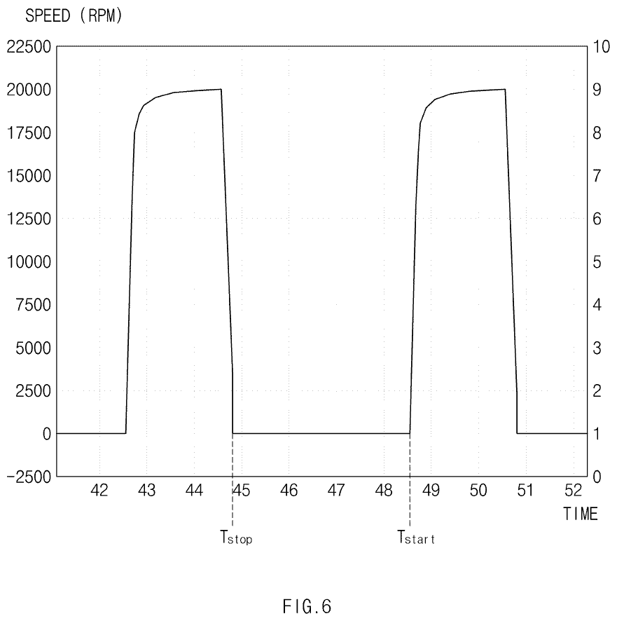

FIG. 6 is a drawing for describing an example of determining a time point when rotor position estimation associated with the present disclosure is performed.

As shown in FIG. 6, a motor control device 200 may estimate a position of a rotor 110 of a motor 100 at a time point Tₛₜₒₚ when the motor 100 stops. Thereafter, when the motor 100 restarts, the motor control device 200 may set a position of the rotor 110, which is estimated at an immediately previous stop time point Tₛₜₒₚ, to an initial position of the rotor 110 of the motor 100 at a restart time point Iₛₜₐᵣₜ. The motor control device 200 may perform initial driving of the rotor 110 of the motor 100 from the set initial position.

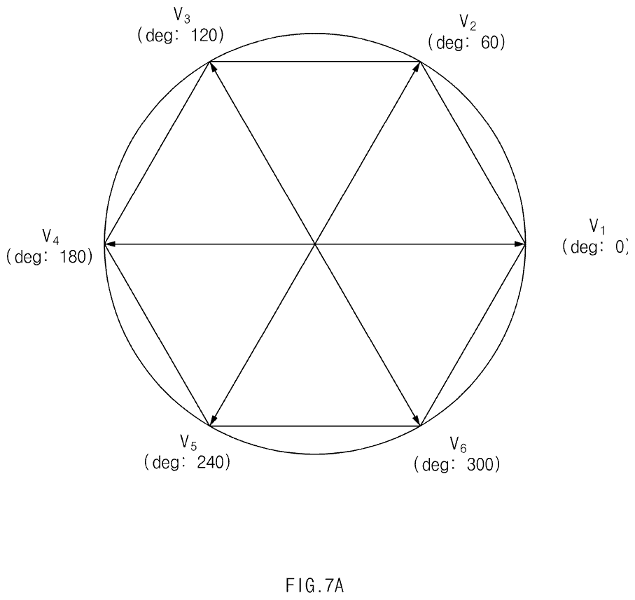

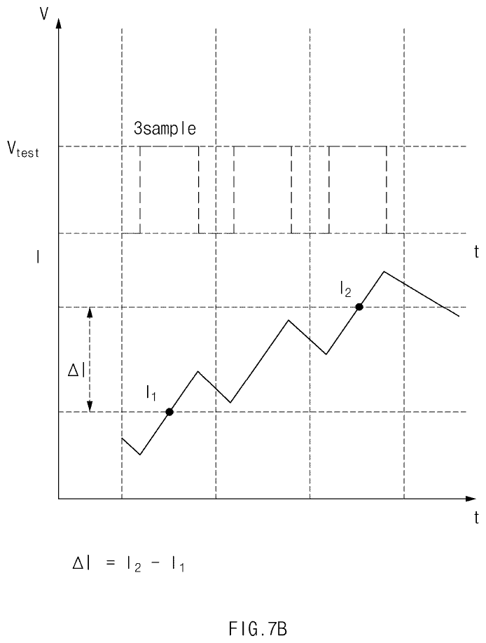

FIGS. 7A and 7B are drawings for describing a rotor initial position estimation scheme associated with the present disclosure.

As shown in FIG. 7A, a processor 250 of a motor control device 200 may control a power supply 210 to apply a phase voltage in the form of a pulse to a stator 120 of the motor 100. The power supply 210 may apply the phase voltage based on predetermined resolution (or a stator interpole spacing). For example, when the resolution is set to 60 degrees, the power supply 210 may apply the phase voltage to the stator 120 at intervals of 60 degrees.

Furthermore, to prevent the rotor 110 from rotating according to a phase voltage application direction (or a counterclockwise direction) when applying the phase voltage to the stator 120, the power supply 210 may apply the phase voltage in the direction of rotation to sequentially apply the phase voltage in the direction of a symmetric phase voltage vector. For example, referring to FIG. 7A, the motor control device 200 may set a phase voltage vector application order to an order of V₁ (0 degree), V₄ (180 degrees), V₂ (60 degrees), V₅ (240 degrees), V₃ (120 degrees), and V₆ (300 degrees).

Referring to FIG. 7B, the motor control device 200 may apply a phase voltage Vₜₑₛₜ to the stator 120 for each position (or each phase voltage vector or each space voltage vector) and may measure current flowing in the stator 120 using a current sensor 220. The motor control device 200 may identify a current deviation for each phase voltage vector and may estimate a position of the rotor 110. The motor control device 200 may identify a current deviation ΔI=I₂−I₁ for each phase voltage vector and may derive an estimated position.

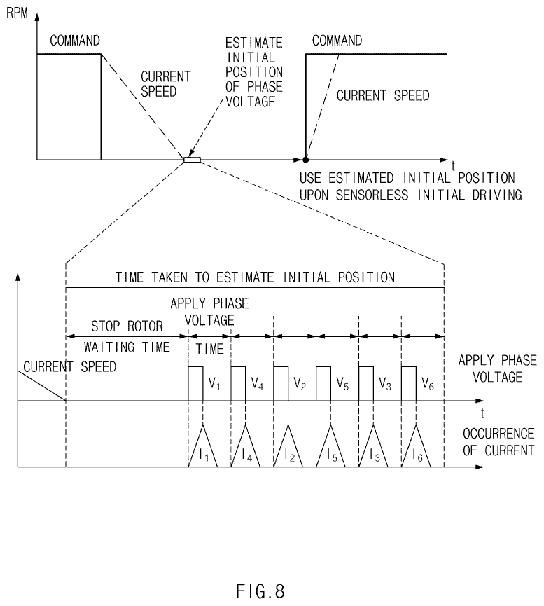

FIG. 8 is a drawing for describing rotor initial position estimation when stopping a motor associated with the present disclosure.

Referring to FIG. 8, a motor control device 200 may estimate a current speed (or a rotation speed) when braking the motor 100. In other words, the motor control device 200 may transmit a stop command to the motor 100 and may estimate a current speed of the motor 100. When the estimated current speed reaches 0 rpm, the motor control device 200 may apply a phase voltage to perform rotor position estimation. There may be a deviation between the estimated current speed and an actual motor rotation speed. In other words, the current speed of the motor 100 is estimated as 0 rpm, but the rotor 110 may be actually rotating. Thus, when the current speed of the motor 100 is estimated as 0 rpm, the motor control device 200 may wait during a predetermined waiting time (or a rotor stop waiting time) and may start to apply a phase voltage. In other words, when it is estimated that the motor 100 stops, the motor control device 200 may wait until the rotor 110 of the motor 100 actually stops and may apply a phase voltage. Because a deviation occurs depending on a type of the motor 100, the waiting time may be preset by testing the motor 100 to be applied to an air compressor.

The motor control device 200 may apply a phase voltage a predetermined number of times when applying the phase voltage. The number of times that the phase voltage is applied may be determined by the number of poles of the stator 120. Furthermore, the motor control device 200 may sense a current (or a phase current) generated whenever the phase voltage is applied.

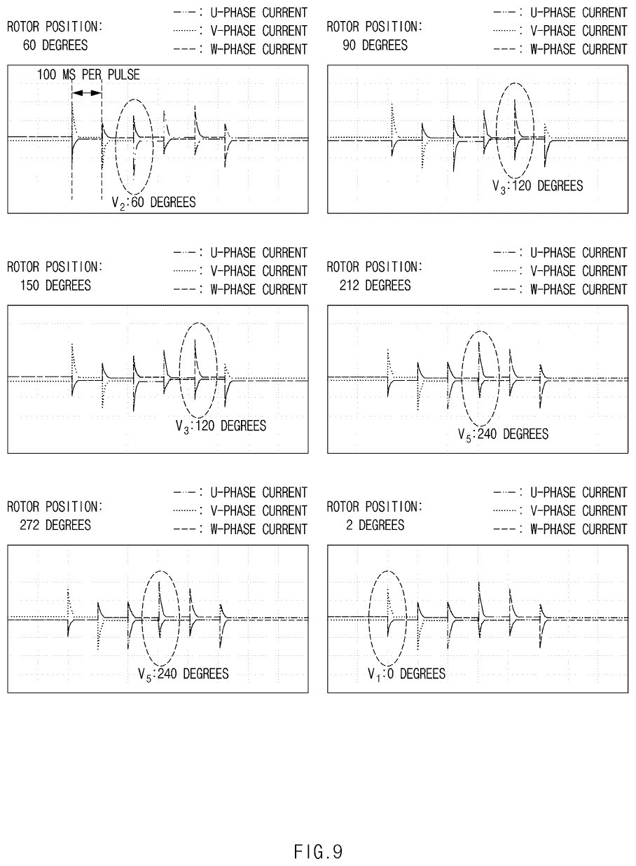

FIG. 9 is a drawing illustrating the result of testing rotor initial position estimation associated with the present disclosure.

A motor control device 200 may apply a 3-phase (or U-phase, V-phase, and W-phase) voltage to a stator 120 of a motor 100 and may measure a value of current flowing in the stator 120. At this time, the motor control device 200 may measure a 3-phase current.

The motor control device 200 may discriminate a position where the largest current value among peak absolute values of the measured current values is measured (or a voltage vector). The motor control device 200 may estimate (or determine) the discriminated position as an initial position of the rotor 110. The motor control device 200 may compare the estimated initial position of the rotor 110 with an actual position of the rotor 110 to identify whether the initial position of the rotor 110 is normally estimated. Referring to FIG. 9, it may be seen that the position of the rotor 110 is normally estimated by the motor control device 200.

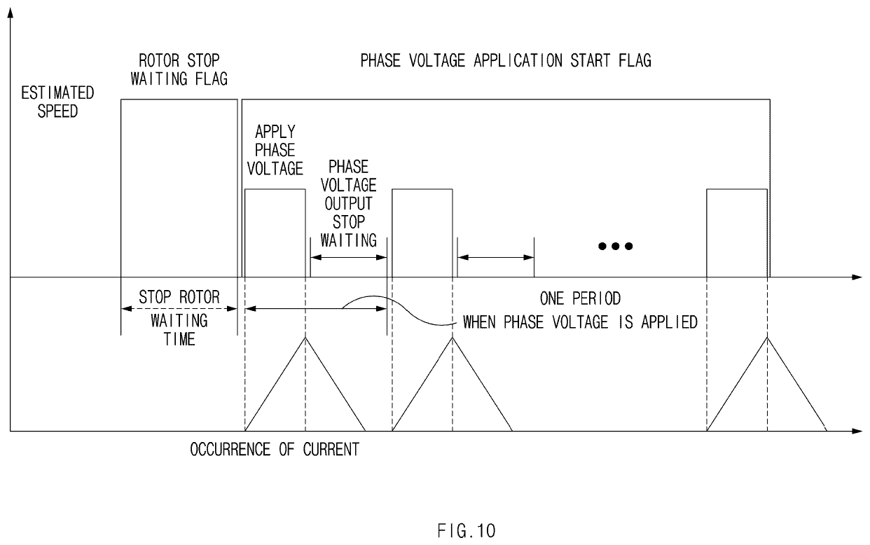

FIG. 10 is a drawing for describing a phase voltage application scheme.

When applying a phase voltage, a motor control device 200 may apply the phase voltage depending on a predetermined pulse duty cycle and may stop a phase voltage output to wait. In other words, a power supply 210 may apply the phase voltage during a predetermined phase voltage output time and may stop the phase voltage output during a predetermined phase voltage output stop waiting time.

Referring to FIG. 10, when a phase voltage is supplied to a stator 120, current flowing in the stator 120 rises and the current flowing in the stator 120 falls from a time point when the phase voltage supplied to the stator 120 is blocked. At this time, the current flowing in the stator 120 may have a certain slope to rise to 0 A during a certain time. This is a phenomenon which occurs when energy charged by an inductance and DC link capacitor component of the rotor 110 is discharged. Because the motor control device 200 should apply a phase voltage when current flowing in the stator 120 is OA, it may block the phase voltage and may wait for a time when the current falls to 0 A to apply a next phase voltage.

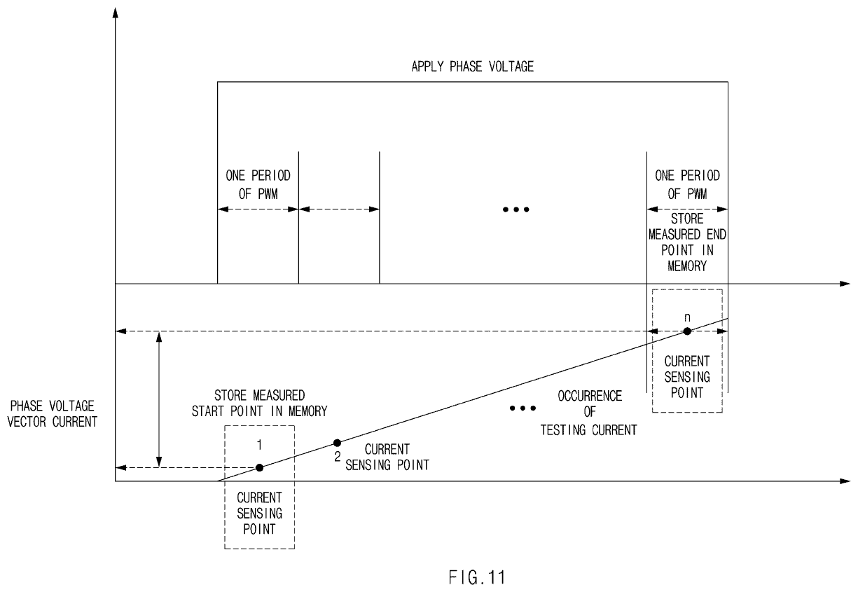

FIG. 11 is a drawing for describing a current measurement scheme.

A motor control device 200 may apply a phase voltage during a predetermined time. For example, the predetermined time may be the number of PWM periods, which may be predetermined by a motor test. While the phase voltage is applied, a phase current linearly rises.

The motor control device 200 may sense a first current value in a first period of PWM and may sense a second current value in a last period of the PWM. The motor control device 200 may calculate a difference between the sensed first current value in the first period and the sensed second current value in the last period. The motor control device 200 may set the calculated current value difference as a phase voltage vector delta current. The motor control device 200 may measure a phase voltage vector delta current for each phase and may store a maximum value. The motor control device 200 may compare maximum values of the phase voltage vector delta currents for each position and may estimate a position with the largest current value as a position of the rotor 110.

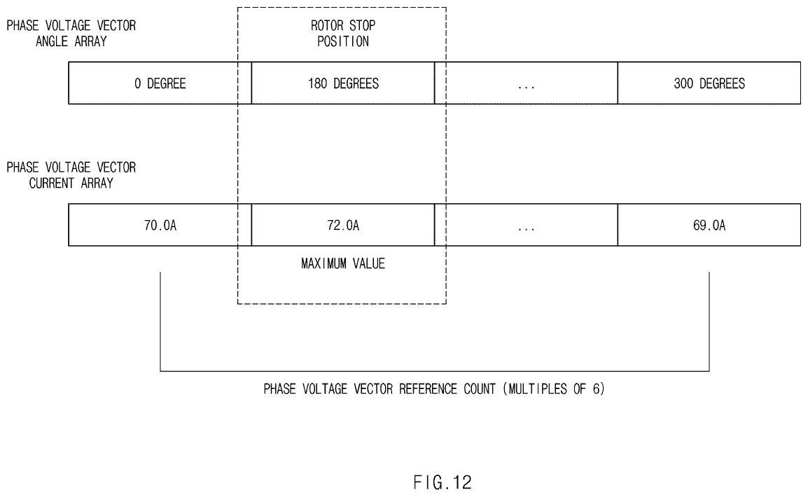

FIG. 12 is a drawing for describing an example of a rotor position derivation scheme.

A motor control device 200 may determine an angle in a phase voltage vector angle array, which corresponds to a position with the largest value in an array of phase voltage vector delta currents (or phase voltage vector currents), as an initial position of a rotor 110. Referring to FIG. 12, when 72.0 A is the maximum value in the phase voltage vector current array, the motor control device 200 may determine an angle of 180 degrees in the phase voltage vector angle array mapped to a position at which the phase current maximum value of 72.0 A is stored in the phase voltage vector current array as an initial position of the rotor 110.

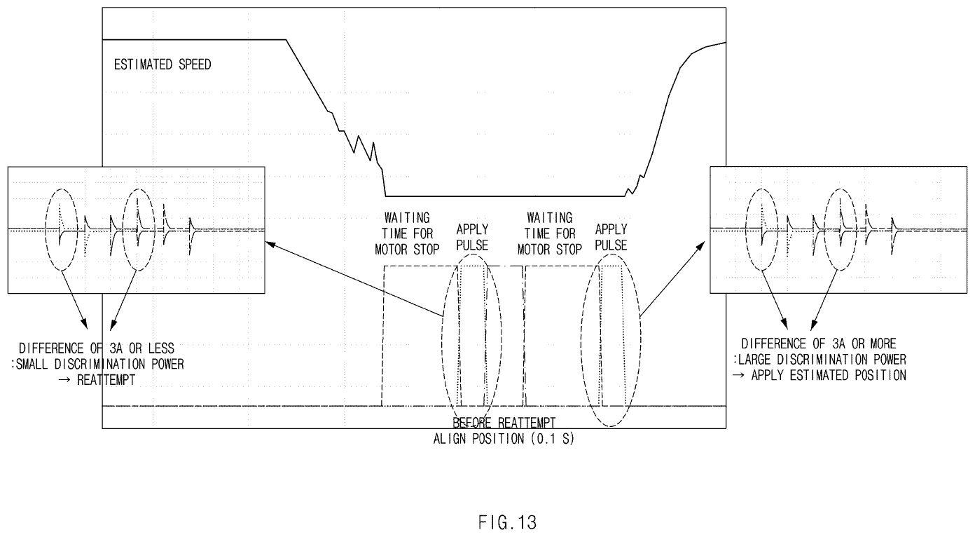

FIG. 13 is a drawing for describing a rotor position estimation reattempt scheme.

After applying a phase voltage, a motor control device 200 may calculate a difference between a first maximum current value and a second maximum current value, which are measured by a current sensor 220. The motor control device 200 may identify whether the calculated current value difference is less than a predetermined reference value. When it is identified that the calculated current value difference is less than the predetermined reference value (e.g., 3A), the motor control device 200 may determine that there is a possibility of an error in rotor position estimation. When it is determined that there is the possibility of the error in rotor position estimation, the motor control device 200 may determine to reattempt to estimate a position of the rotor 110. In other words, when the calculated current value difference is less than the predetermined reference value, the motor control device 200 may determine to reattempt to estimate the position of the rotor 110. When it is determined to reattempt to estimate the position of the rotor 110, the motor control device 200 may reapply a phase voltage.

Furthermore, before reapplying the phase voltage, the motor control device 200 may change the position of the rotor 110. For example, the motor control device 200 may apply a predetermined current (e.g., 35 A) to a d-axis (or a 0-degree position) on a stationary coordinate system of a stator 120 during a predetermined time (e.g., 0.1 second) to change the position of the rotor 110.

After changing the position of the rotor 110, the motor control device 200 may reapply the phase voltage. After reapplying the phase voltage again, the motor control device 200 may measure current values using a current sensor 220. The motor control device 200 may calculate a difference between a first maximum current value and a second maximum current value among the measured current values. When the calculated current value difference is greater than or equal to a predetermined reference value, the motor control device 200 may determine (or estimate) the currently estimated position as a final position of the rotor 110. The number of reattempts may be limited to a predetermined number of times (e.g., 3 times).

When the position of the rotor 110 is a boundary point of position resolution or when the current deviation is not significant at a specific position by a motor manufacture deviation, as the discrimination power of a maximum current waveform is lowered, there may be a possibility of an error in rotor position estimation. In other words, as the difference between the first maximum current value and the second maximum current value decreases to a certain level or less, an incorrect position may be estimated. Thus, when the difference between the first maximum current value and the second maximum current value is smaller than a reference current value, the motor control device 200 may reapply the phase voltage again and may execute rotor position estimation again. Because the same problem is repeated when reattempting to reapply the phase voltage, the motor control device 200 may apply a current to a predetermined specific position of the stator 120 to rotate the rotor 110 and may change a position of the rotor 110, before reapplying the phase voltage, and may reapply the phase voltage. As such, the motor control device 200 may improve the accuracy of initial position estimation of the rotor 110.

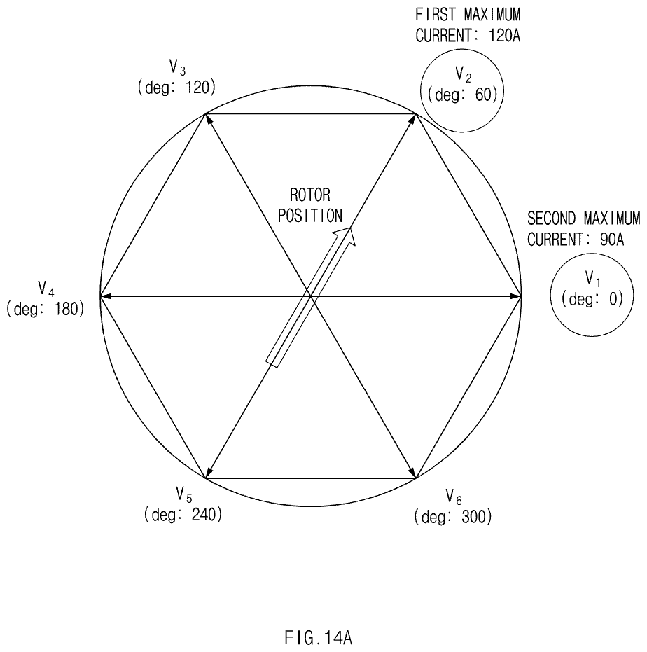

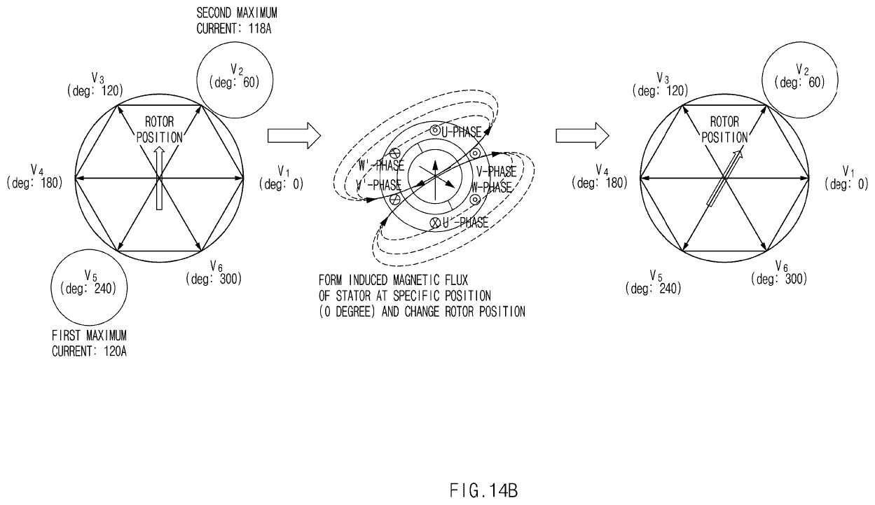

FIG. 14A is a drawing for describing normal rotor position estimation. FIG. 14B is a drawing for describing rotor position re-estimation.

Referring to FIG. 14A, when a first maximum current value is 120 A and when a second maximum current value is 90 A, a motor control device 200 may calculate a difference between the first maximum current value and the second maximum current value. When the calculated current value difference is 30 A and is greater than a predetermined reference value of 3 A, the motor control device 200 may determine a position at which the first maximum current value is measured, that is, 60 degrees as an initial position of a rotor 110.

Referring to FIG. 14B, when the first maximum current value is 120 A and when the second maximum current value is 118 A, the motor control device 200 may calculate a difference between the first maximum current value and the second maximum current value and may identify whether the calculated current value difference of 2 A is less than the predetermined reference value of 3 A. When the calculated current value difference is less than the predetermined reference value, the motor control device 200 may form an induced magnetic flux at a specific position (e.g., 0 degree) of a stator 120 and may change a position of the rotor 110. After changing the position of the rotor 110, the motor control device 200 may reapply a phase voltage and may re-estimate a position of the rotor 110. For example, when the difference between the first maximum current value and the second maximum current value among the current values measured after reapplying the phase voltage is greater than or equal to the predetermined reference value, the motor control device 200 may finally determine 60 degrees at which the first maximum current value is measured as an initial position of the rotor 110.

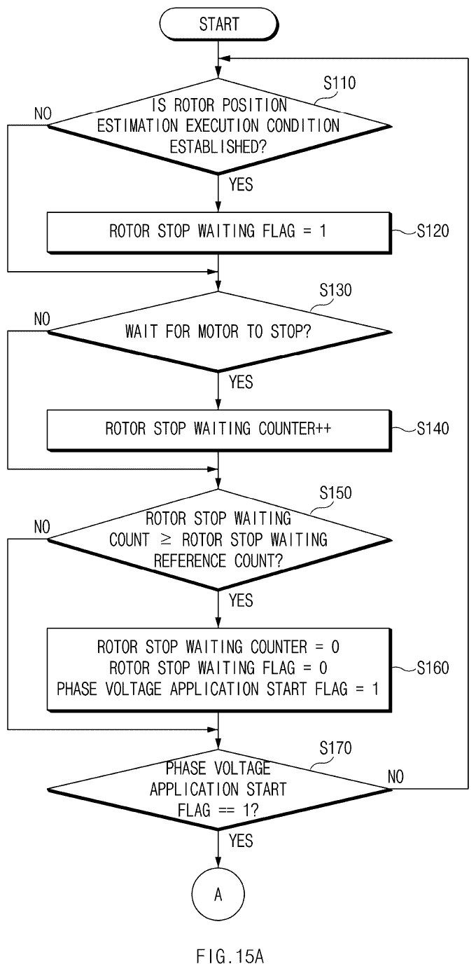

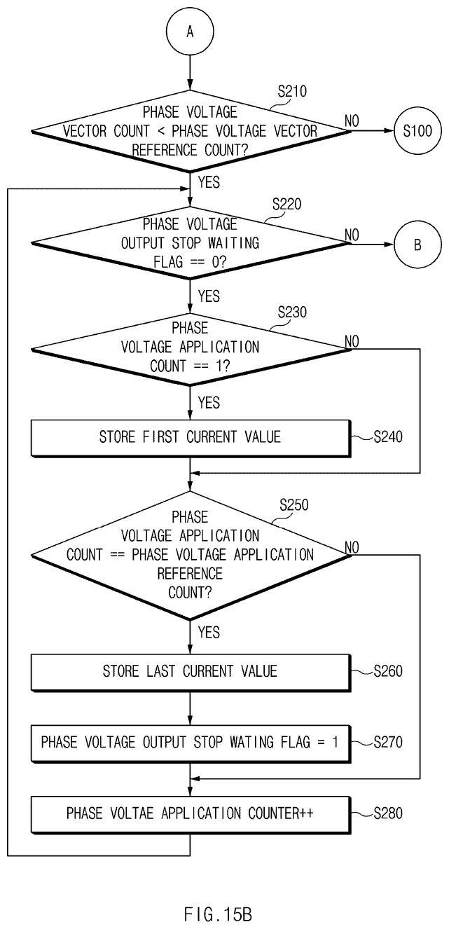

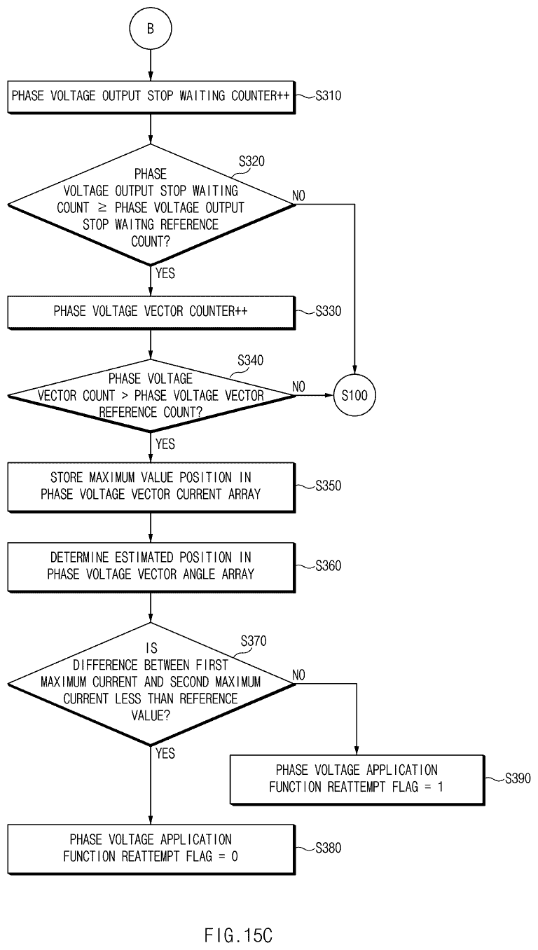

FIGS. 15A to 15C are flowcharts illustrating an example of a method for estimating a position of a rotor of a motor.

In S110, a processor 250 of a motor control device 200 may determine whether a rotor position estimation execution condition is established. The processor 250 may determine whether the rotor position estimation execution condition is established based on a speed command, an estimated speed in an immediately previous period, an estimated speed in a current period, and/or the like. As an example, when the speed command transmitted to a motor 100 is 0 rpm and when the speed (or the motor speed) estimated in the immediately previous period is not 0 rpm and the speed estimated in the current period is 0 rpm, the processor 250 may determine that the rotor position estimation execution condition is established.

When it is determined that the rotor position estimation execution condition is established, in S120, the processor 250 may determine to wait for a rotor 110 to stop. The processor 250 may set a rotor stop waiting flag to “1”. In some examples, when it is determined that the rotor position estimation execution condition is not established, the processor 250 may perform S130.

In S130, the processor 250 may determine whether to wait for the motor 100 to stop. The processor 250 may identify whether the rotor stop waiting flag is set to “1”. When the rotor stop waiting flag is set to “1”, the processor 250 may determine to wait for the motor 100 to stop.

When it is determined for the motor 100 to stop, in S140, the processor 250 may increase a rotor stop waiting counter by “+1” every period. The processor 250 may count a rotor stop waiting time. When it is determined that the operation state is not a motor stop waiting state, the processor 250 may perform S150.

In S150, the processor 250 may identify whether a rotor stop waiting count output from the rotor stop waiting counter is greater than or equal to a rotor stop waiting reference count. The processor 250 may determine whether the counted rotor stop waiting time is greater than a predetermined reference waiting time. The processor 250 may count a time waiting until the rotor 110 stops (i.e., the rotor stop waiting count) using the rotor stop waiting counter.

When the rotor stop waiting count is greater than or equal to the rotor stop waiting reference count, in S160, the processor 250 may set a phase voltage application start flag to “1”. In other words, when the counted rotor stop waiting time is greater than the predetermined reference waiting time, the processor 250 may determine to apply a phase voltage. Furthermore, the processor 250 may initialize the rotor stop waiting counter to “0” and may also initialize a rotor stop waiting flag to “0”. When the rotor stop waiting count is less than the rotor stop waiting reference count, the processor 250 may perform S170.

In S170, the processor 250 may identify whether the phase voltage application start flag is set to “1”.

When the phase voltage application start flag is set to “1”, in S210, the processor 250 may identify whether the phase voltage vector count is less than a predetermined phase voltage vector reference count (e.g., 6). The processor 250 may apply a phase voltage and may increase the phase voltage vector counter by “1” when the application of the phase voltage is completed. The phase voltage vector reference count may be determined by the number of poles of the stator 120 (i.e., the number of divided space voltage vectors). In some examples, when the phase voltage application start flag is set to “1”, the processor 250 may return to S110.

When the phase voltage vector count is less than the predetermined phase voltage vector reference count, in S220, the processor 250 may identify whether a phase voltage output stop waiting flag is “0”.

When the phase voltage output stop waiting flag is “0”, in S230, the processor 250 may identify whether a phase voltage application count is “1”. The processor 250 may identify whether the phase voltage application count output from a phase voltage application counter is “1”. In some examples, when the phase voltage output stop waiting flag is “1”, the processor 250 may perform the operation from S310.

When the phase voltage application count is “1”, in S240, the processor 250 may store a first current value. When the phase voltage application count is “0”, the processor 250 may perform the operation from S250.

In S250, the processor 250 may identify whether the phase voltage application count is identical to a predetermined phase voltage application reference count.

When the phase voltage application count is identical to the phase voltage application reference count, in S260, the processor 250 may store a last current value. When the phase voltage application count is not identical to the phase voltage application reference count, the processor 250 may perform the operation from S280.

After storing the last current value, in S270, the processor 250 may set the phase voltage output stop waiting flag to “1”.

In S280, the processor 250 may increase the phase voltage application counter by “+1”. Thereafter, the processor 250 may return to S220.

When the phase voltage output stop waiting flag is not “0” in S220, in S310, the processor 250 may increase the phase voltage output stop waiting counter by “+1”. In other words, when the phase voltage output stop waiting flag is “1”, the processor 250 may increase the phase voltage output stop waiting counter by “+1”.

In S320, the processor 250 may identify whether the phase voltage output stop waiting count counted by the phase voltage output stop waiting counter is greater than or equal to a predetermined phase voltage output stop waiting reference count. The processor 250 may increase the phase voltage output stop waiting counter by “1” every PWM period and may wait until the phase voltage output stop waiting count reaches the predetermined phase voltage output stop waiting reference count.

When the phase voltage output stop waiting count is greater than or equal to the predetermined phase voltage output stop waiting reference count, in S330, the processor 250 may increase the phase voltage vector counter. When the application of the phase voltage is completed for each position, the processor 250 may increase the phase voltage vector counter by “1”. The phase voltage vector counter may output the increased phase voltage vector count to the processor 250.

In S340, the processor 250 may identify whether the phase voltage vector count is greater than a phase voltage vector reference count. In other words, the processor 250 may determine whether the application of the phase voltage to six positions is completed. When the phase voltage output stop waiting count counted in S320 is less than the predetermined phase voltage output stop waiting reference count or when the phase voltage vector count is less than or equal to the phase voltage reference count in S340, the processor 250 may return to S100.

When the phase voltage vector count is greater than the phase voltage vector reference count, in S350, the processor 250 may store a maximum value position in a phase voltage vector current array. The processor 250 may identify a position of a maximum current value in a phase voltage vector current array.

In S360, the processor 250 may determine an estimated position in a phase voltage vector angle array. The processor 250 may estimate a phase voltage vector angle mapped to the maximum current value position in the phase voltage vector current array in the phase voltage vector angle array as a rotor position.

Next, in S370, the processor 250 may identify whether a difference between a first maximum current value and a second maximum current value is less than a predetermined reference value.

When the difference between the first maximum current value and the second maximum current value is less than the predetermined reference value, in S380, the processor 250 may set a phase voltage application function reattempt flag to “1”. When the difference between the first maximum current value and the second maximum current value is less than the predetermined reference value, the processor 250 may reattempt to estimate a position of the rotor 110.

When the difference between the first maximum current value and the second maximum current value is not less than the predetermined reference value, in S390, the processor 250 may set the phase voltage application function reattempt flag to “0”. When the difference between the first maximum current value and the second maximum current value is not less than the predetermined reference value, the processor 250 may not reattempt to estimation the position of the rotor 110 and may determine the rotor position estimated in S360 as a final rotor position.

Implementations of the present disclosure may apply a pulse voltage application scheme to improve the accuracy of the estimation of an initial position of the rotor even in a state in which the motor is stopped.

Furthermore, implementations of the present disclosure may improve initial driving control stability when performing position sensorless control in the stopped state.

Hereinabove, although the present disclosure has been described with reference to exemplary implementations and the accompanying drawings, the present disclosure is not limited thereto, but may be variously modified and altered by those skilled in the art to which the present disclosure pertains without departing from the spirit and scope of the present disclosure claimed in the following claims. Therefore, implementations of the present disclosure are not intended to limit the technical spirit of the present disclosure, but provided only for the illustrative purpose. The scope of the present disclosure should be construed on the basis of the accompanying claims, and all the technical ideas within the scope equivalent to the claims should be included in the scope of the present disclosure.

What is claimed is:

1. A motor control device, comprising:
a power supply configured to supply a phase voltage to a stator of a motor;
a current sensor configured to measure a stator current in the stator; and
a processor connected to the power supply and the current sensor,
wherein the processor is configured to:
determine whether a rotor position estimation execution condition is established,
apply the phase voltage to the stator of the motor based on determining that the rotor position estimation execution condition is established,
measure the stator current,
estimate a position of a rotor of the motor based on a first maximum current value among a plurality of measured current values of the stator current, and
determine whether to reattempt to estimate the position of the rotor based on a difference between the first maximum current value and a second maximum current value among the plurality of measured current values.

2. The motor control device of claim 1, wherein the processor is configured to:
determine whether the difference between the first maximum current value and the second maximum current value is less than a predetermined reference value; and
determine to reattempt to estimate the position of the rotor based on determining that the difference between the first maximum current value and the second maximum current value is less than the predetermined reference value.

3. The motor control device of claim 1, wherein the processor is configured to:
change the position of the rotor based on determining to reattempt to estimate the position of the rotor; and
re-estimate the position of the rotor by reapplying the phase voltage to the stator after changing the position of the rotor.

4. The motor control device of claim 1, wherein the processor is configured to set the estimated position of the rotor as an initial position of the rotor based on determining not to reattempt to estimate the position of the rotor.

5. The motor control device of claim 1, wherein the processor is configured to determine that the rotor position estimation execution condition is established based on the motor switching from a rotational state to a stopped state in response to a stop command being transmitted to the motor.

6. The motor control device of claim 1, wherein the processor is configured to:
determine whether a predetermined time has elapsed until the rotor of the motor stops rotating; and
initiate to apply the phase voltage to the stator based on determining that the predetermined time has elapsed.

7. The motor control device of claim 1, wherein the processor is configured to:
intermittently apply the phase voltage to the stator based on a predetermined pulse duty cycle;
determine whether the stator current is blocked; and
apply a next phase voltage based on the stator current being blocked.

8. The motor control device of claim 1, wherein the phase voltage comprises a 3-phase voltage having one or more pulses.

9. The motor control device of claim 1, wherein the processor is configured to:
sense, by the current sensor, a first current value of the stator current in a first period of a pulse width modulation (PWM) of the phase voltage;
sense, by the current sensor, a second current value of the stator current in a last period of the PWM;
calculate a current value difference between the first current value and the second current value; and
set a phase voltage vector current based on the calculated current value difference.

10. The motor control device of claim 1, wherein the processor is configured to:
identify a position corresponding to the first maximum current value in a phase voltage vector current array, the phase voltage vector current array including a plurality of current difference values between the plurality of measured current values; and
determine the position of the rotor based on an angle in a phase voltage vector angle array that is mapped to the identified position corresponding to the first maximum current value, the phase voltage vector angle array including a plurality of angles that are mapped to a plurality of positions corresponding to a plurality of maximum current values.

11. A method for estimating a position of a rotor of a motor, the method comprising:
determining whether a rotor position estimation execution condition is established;
applying a phase voltage to a stator of the motor based on determining that the rotor position estimation execution condition is established;
measuring a stator current in the stator of the motor;
estimating the position of the rotor of the motor based on a first maximum current value among a plurality of measured current values; and
determining whether to reattempt to estimate the position of the rotor based on a difference between the first maximum current value and a second maximum current value among the plurality of measured current values.

12. The method of claim 11, further comprising:
determining whether the difference between the first maximum current value and the second maximum current value is less than a predetermined reference value; and
determining to reattempt to estimate the position of the rotor based on determining that the difference between the first maximum current value and the second maximum current value is less than the predetermined reference value.

13. The method of claim 11, further comprising:
changing the position of the rotor based on determining to reattempt to estimate the position of the rotor; and
re-estimating the position of the rotor by reapplying the phase voltage to the stator after changing the position of the rotor.

14. The method of claim 11, further comprising:
determining the estimated position of the rotor as an initial position of the rotor based on determining not to reattempt to estimate the position of the rotor.

15. The method of claim 11, further comprising:
determining that the rotor position estimation execution condition is established based on the motor switching from a rotational state to a stopped state in response to a stop command being transmitted to the motor.

16. The method of claim 11, further comprising:
determining whether a predetermined time has elapsed until the rotor of the motor stops rotating; and
initiating to apply the phase voltage to the stator based on determining that the predetermined time has elapsed.

17. The method of claim 11, wherein applying the phase voltage to the stator of the motor comprises:
intermittently applying the phase voltage to the stator based on a predetermined pulse duty cycle;
determining whether the stator current is blocked; and
applying a next phase voltage based on the stator current being blocked.

18. The method of claim 11, wherein the phase voltage comprises a 3-phase voltage having one or more pulses.

19. The method of claim 11, wherein measuring the stator current comprises:
sensing a first current value of the stator current in a first period of a pulse width modulation (PWM) of the phase voltage;
sensing a second current value of the stator current in a last period of the PWM;
calculating a current difference value between the first current value and the second current value; and
setting a phase voltage vector current based on the calculated current value difference.

20. The method of claim 11, wherein estimating the position of the rotor comprises:
identifying a position corresponding to the first maximum current value in a phase voltage vector current array, the phase voltage vector current array including a plurality of current difference values between the plurality of measured current values; and
determining the position of the rotor based on an angle in a phase voltage vector angle array that is mapped to the identified position corresponding to the first maximum current value, the phase voltage vector angle array including a plurality of angles that are mapped to a plurality of positions corresponding to a plurality of maximum current values.
